(19) United States
(12) Patent Application Publication
(10) Pub. No.: US 2025/0192079 A1
(43) Pub. Date: Jun. 12, 2025

(54) ANTENNA DEVICE

(71) Applicant: AUO Corporation, Hsinchu City (TW)

(72) Inventors: Yi-Cheng Lai, Hsinchu City (TW); Chung-Hung Chen, Hsinchu City (TW); Yu-Chih Wang, Hsinchu City (TW); Shih-Hsien Yang, Hsinchu City (TW)

(73) Assignee: AUO Corporation, Hsinchu City (TW)

(21) Appl. No.: 18/970,902

(22) Filed: Dec. 6, 2024

Related U.S. Application Data
(60) Provisional application No. 63/606,806, filed on Dec. 6, 2023.

(30) Foreign Application Priority Data
Jul. 18, 2024 (TW) 113126978
Nov. 14, 2024 (TW) 113143748

(51) Int. Cl. H01L 23/66; H01L 23/498; H01L 25/18

(52) U.S. Cl. CPC H01L 23/66; H01L 23/49822; H01L 23/49838; H01L 25/18; H01L 2223/6616; H01L 2223/6677

(57) ABSTRACT

An antenna device includes a transparent substrate, a thin film circuit structure, a redistribution structure, multiple chips, and multiple antenna electrodes. The thin film circuit structure is located above a first surface of the transparent substrate and includes a first thin film conductive layer. The redistribution structure is located on the thin film circuit structure and includes a first redistribution layer. A thickness of the first thin film conductive layer is less than a thickness of the first redistribution layer. The chips are bonded to the redistribution structure. The antenna electrodes are located above a second surface of the transparent substrate opposite to the first surface. Each of the antenna electrodes overlaps a corresponding one of the chips.

### CROSS-REFERENCE TO RELATED APPLICATION

This application claims the priority benefit of U.S. provisional application Ser. No. 63/606,806, filed on Dec. 6, 2023, Taiwan application serial no. 113126978, filed on Jul. 18, 2024, and Taiwan application serial no. 113143748, filed on Nov. 14, 2024. The entirety of each of the above-mentioned patent applications is hereby incorporated by reference herein and made a part of this specification.

### BACKGROUND

### Technical Field

The disclosure relates to an antenna device.

### Description of Related Art

In modern life, the application of wireless communication technology has become ubiquitous. Providing wireless local area network has become a necessary facility in important cities or public spaces, and many people have even established their own wireless networks at home. With the advancement of wireless communication technology, many manufacturers are committed to developing antenna devices with improved performance. Currently, the antenna device has a complex internal circuit design, involving various different signals. If the distance between signal lines is too close, signals will easily interfere with each other, thereby affecting the performance of the antenna device.

### SUMMARY

At least one embodiment of the disclosure provides an antenna device, including a transparent substrate, a thin film circuit structure, a redistribution structure, multiple chips, and multiple antenna electrodes. The thin film circuit structure is located above the first surface of the transparent substrate and includes a first thin film conductive layer. The redistribution structure is located on the thin film circuit structure and includes a first redistribution layer. A thickness of the first thin film conductive layer is less than a thickness of the first redistribution layer. The chips are bonded to the redistribution structure. The antenna electrodes are located above a second surface of the transparent substrate opposite to the first surface. Each antenna electrode overlaps a corresponding one of the chips.

### BRIEF DESCRIPTION OF THE DRAWINGS

FIG. 1 is a schematic top view of an antenna device according to an embodiment of the disclosure.

FIG. 2 is a schematic cross-sectional view of an antenna device according to an embodiment of the disclosure.

FIG. 3 is a schematic top view of an antenna device according to an embodiment of the disclosure.

FIG. 4 is a radio frequency signal transmission manner of some antenna devices according to some embodiments of the disclosure.

FIG. 5 is a radio frequency signal transmission manner of other antenna devices according to some embodiments of the disclosure.

FIG. 6 is a schematic view of data writing/selection of an antenna device according to some embodiments of the disclosure.

FIG. 7 is a functional block diagram of an antenna device according to an embodiment of the disclosure.

FIG. 8 is a schematic top view of an antenna device according to an embodiment of the disclosure.

FIG. 9 is a schematic cross-sectional view of an antenna device according to an embodiment of the disclosure.

FIG. 10 is a schematic top view of an antenna device according to an embodiment of the disclosure.

FIG. 11 is a schematic view of data writing/selection of an antenna device according to some embodiments of the disclosure.

FIG. 12 is a functional block diagram of an antenna device according to an embodiment of the disclosure.

FIG. 13 is a schematic circuit diagram of an antenna unit according to an embodiment of the disclosure.

FIG. 14 is a schematic circuit diagram of a memory circuit of an antenna unit according to an embodiment of the disclosure.

FIG. 15 is a functional block diagram of an antenna device according to an embodiment of the disclosure.

FIG. 16 is a functional block diagram of another antenna device according to an embodiment of the disclosure.

FIG. 17 is a functional block diagram of yet another antenna device according to an embodiment of the disclosure.

### DESCRIPTION OF THE EMBODIMENTS

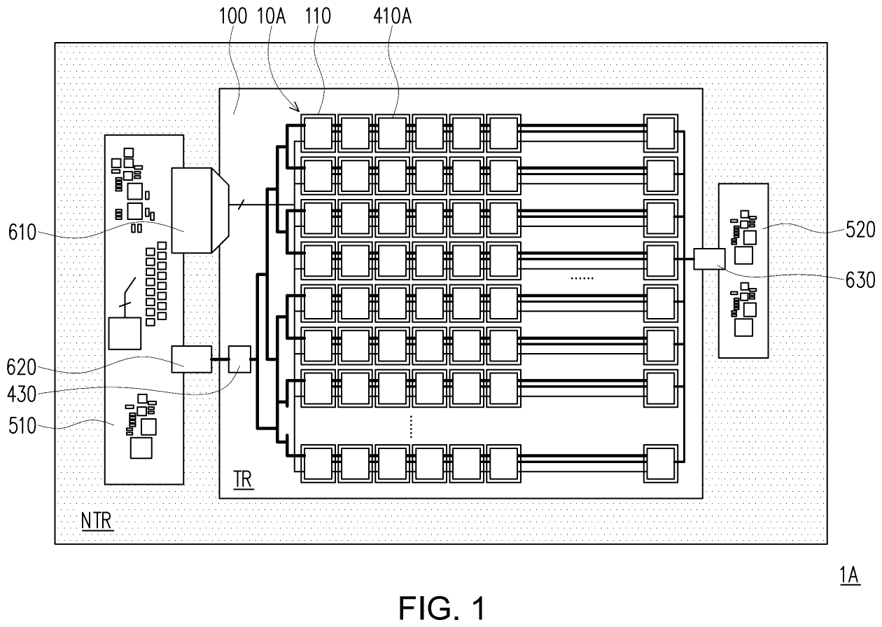

FIG. 1 is a schematic top view of an antenna device 1A according to an embodiment of the disclosure. Please refer to FIG. 1. The antenna device 1A includes a transparent substrate 100 and multiple antenna units 10A disposed on the transparent substrate 100. The antenna units 10A are, for example, arranged in an array. In the embodiment, at least one printed circuit board 510, 520 is electrically connected to the array of the antenna units 10A through at least one flexible circuit board 610, 620, 630. Each antenna unit 10A includes an antenna electrode 110 and a chip 410A electrically connected to the antenna electrode 110.

In the embodiment, the antenna device 1A includes the printed circuit boards 510 and 520 and the flexible circuit boards 610, 620, and 630. The printed circuit boards 510 and 520 are electrically connected to a redistribution structure (not shown in FIG. 1) on the transparent substrate 100 through the flexible circuit boards 610, 620, and 630, and are further electrically connected to the array of the antenna units 10A. In the embodiment, multiple chips are disposed on each printed circuit board 510, 520. In some embodiments, the printed circuit boards 510 and 520 include modulator/demodulators (MODEM), field programmable gate arrays (FPGA), digital to analog converters (DAC), analog to digital converters (ADC), power modules, global positioning systems (GPS), G-sensors, etc., and the above elements may be disposed in one or more chips.

In some embodiments, the modulator/demodulator is a device for encoding a digital signal and then modulating the digital signal to an analog signal for transmission, and demodulating the received analog signal and then decoding the analog signal to be converted into a digital signal.

The printed circuit boards 510 and 520 are electrically connected to the array of the antenna units 10A through the flexible circuit boards 610, 620, and 630.

The chip 410A includes a beamformer integrated circuit (BFIC) or other active/passive elements. The chip 410A may perform transmit beamforming (TX) and/or receive beamforming (RX).

In the embodiment, the antenna device 1A further includes an up/down converter (UDC) 430. The up/down converter 430 may be a chip connected to the redistribution structure on the transparent substrate 100 or a circuit directly manufactured on the transparent substrate 100. The printed circuit board 510 is electrically connected to the up/down converter 430 through the flexible circuit board 620 and the redistribution structure on the transparent substrate 100, and the up/down converter 430 is electrically connected to the chip 410A of the antenna unit 10A through the redistribution structure on the transparent substrate 100. For example, the printed circuit board 510 provides a signal with a relatively low frequency (for example, an intermediate frequency (IF) signal or a low frequency signal with a frequency below 10 GHz (for example, below 2 GHZ)), and the signal is transmitted to the up/down converter 430 via the flexible circuit board 620, and the signal frequency is then increased to become a radio frequency signal with a high frequency (for example, 10 to 300 GHz) by the up/down converter 430. In the embodiment, since the up/down converter 430 is disposed above the transparent substrate 100 instead of being disposed on the printed circuit board 510, there is no need to dispose an SMA connector for transmitting the radio frequency signal on the transparent substrate 100.

The antenna device 1A includes a transparent region TR and a non-transparent region NTR. In some embodiments, the printed circuit boards 510 and 520 are disposed in the non-transparent region NTR, and the antenna electrode 110 and the chip 410A of the antenna unit 10A are disposed in the transparent region TR. In some embodiments, the up/down converter 430 is also disposed in the transparent region TR. In some embodiments, the antenna device 1A may be, for example, applied to a window of a vehicle (for example, a sunroof of a car), a window of a building, etc.

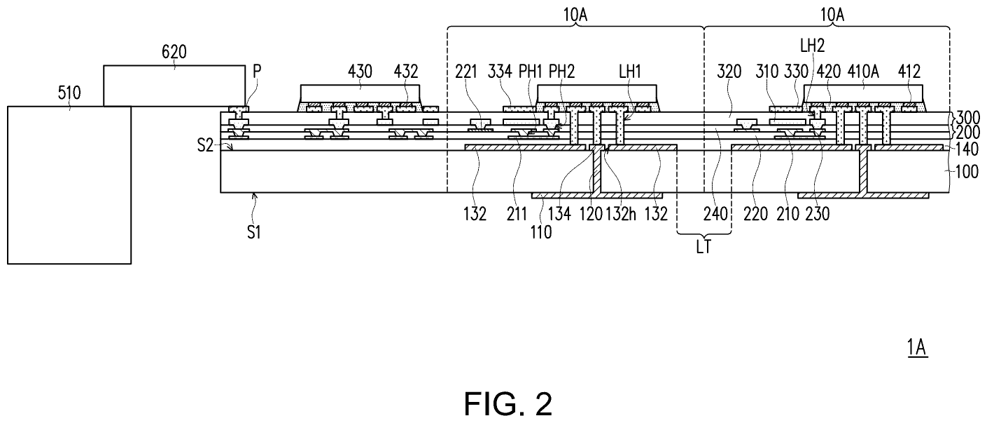

FIG. 2 is a schematic cross-sectional view of the antenna device 1A according to an embodiment of the disclosure. The transparent substrate 100 has a first surface S1 and a second surface S2 opposite to the first surface S1. In some embodiments, the material of the transparent substrate 100 includes glass, quartz, organic polymer, or other applicable materials. In some embodiments, the transparent substrate 100 has a thickness of 0.15 mm to 1.1 mm. For example, the thickness of the transparent substrate 100 is 0.5 mm, 0.7 mm, or 1.1 mm.

The antenna electrode 110 is disposed on the first surface S1 of the transparent substrate 100.

A ground electrode 132 is disposed on the second surface S2 of the transparent substrate 110. In the embodiment, the ground electrode 132 has at least one opening 132h, and each opening 132h has a bonding structure 134. The bonding structure 134 is electrically connected to the antenna electrode 110 through a substrate conductive via 120. Therefore, an antenna signal of the antenna electrode 110 may be transmitted through the bonding structure 134 and the substrate conductive via 120. In other embodiments, the substrate conductive via 120 may be omitted, and the antenna signal of the antenna electrode 110 is transmitted by radiation between the antenna electrode 110 and a driving electrode (not shown) overlapping the opening 132h.

In some embodiments, the width of the ground electrode 132 is greater than or equal to the width of the antenna electrode 110.

In some embodiments, the materials of the antenna electrode 110, the ground electrode 132, the bonding structure 134, and the substrate conductive via 120 include copper (Cu), aluminum (Al), gold (Au), silver (Ag), titanium (Ti), Nickel (Ni), tungsten (W), conductive oxide (for example, indium tin oxide, indium zinc oxide, etc.), other suitable materials, or combinations of the above materials.

In some embodiments, the manner of forming the substrate conductive via 120 includes a glass modification process and a process of filling a conductive material. For example, the glass modification process includes first forming a through hole on the transparent substrate 100 with a laser, and then enlarging the through hole using a wet etching process to form a via extending from the first surface S1 to the second surface S2. Finally, the conductive material is filled into the via to form the substrate conductive via 120.

In some embodiments, the method of forming the antenna electrode 110, the ground electrode 132, the bonding structure 134, and the substrate conductive via 120 includes first forming a seed layer on the first surface S1 and the second surface S2 of the transparent substrate 100 and in the via of the transparent substrate 100 through sputtering, chemical plating, or other suitable processes. Then, a metal layer is formed on the seed layer using an electroplating process. The formed seed layer and metal layer may be patterned through a photolithography process and an etching process to obtain the antenna electrode 110, the ground electrode 132, and the bonding structure 134. In other embodiments, the seed layer may be omitted.

The buffer layer 140 is located on the transparent substrate 100, the ground electrode 132, and the bonding structure 134. In some embodiments, the buffer layer 140 includes a transparent material, such as an organic material (for example, polyimide, polyethylene terephthalate, epoxy resin, etc.), an inorganic material (for example, silicon nitride, silicon oxide, etc.), or a combination of the above materials. In some embodiments, the thicknesses of the antenna electrode 110, the ground electrode 132, and the bonding structure 134 are 2 μm to 10 μm. In order to achieve planarization, the thickness of the buffer layer 140 is preferably 2 μm to 15 μm, and the thickness of the buffer layer 140 is not less than the thickness of the ground electrode 132. For example, the thickness of the buffer layer 140 is 1.3 times the thickness of the ground electrode 132. In order to achieve the thickness to achieve planarization, the buffer layer 140 is preferably made of an organic material.

A thin film circuit structure 200 is located above the ground electrode 132 and the bonding structure 134. In the embodiment, the thin film circuit structure 200 is located on the buffer layer 140. In some embodiments, the overall thickness of the thin film circuit structure 200 is less than 10 μm.

The thin film circuit structure 200 includes a first thin film conductive layer 210, a first dielectric layer 220, a second thin film conductive layer 230, and a second dielectric layer 240 that are sequentially deposited. In some embodiments, at least one contact portion PH1 of the second thin film conductive layer 230 passes through the first dielectric layer 220 and is electrically connected to the first thin film conductive layer 210. In some embodiments, the thin film circuit structure 200 may also include more conductive layers and dielectric layers. The disclosure does not limit the number of conductive layers and dielectric layers in the thin film circuit structure 200.

In some embodiments, the materials of the first thin film conductive layer 210 and the second thin film conductive layer 230 include copper (Cu), aluminum (Al), gold (Au), silver (Ag), titanium (Ti), nickel (Ni), tungsten (W), conductive oxides (for example, indium tin oxide, indium zinc oxide, etc.), other suitable materials, or combinations of the above materials. Each of the first thin film conductive layer 210 and the second thin film conductive layer 230 has a single-layer structure or a multi-layer structure. For example, each of the first thin film conductive layer 210 and the second thin film conductive layer 230 has a molybdenum/aluminum/molybdenum laminate structure, a titanium/aluminum/titanium laminate structure, or a laminate structure composed of other conductive materials.

In some embodiments, the materials of the first dielectric layer 220 and the second dielectric layer 240 include organic polymers (for example, polyimide, polyethylene terephthalate, etc.), inorganic materials (for example, silicon oxide, silicon nitride, silicon oxynitride, aluminum oxide, zirconium oxide, hafnium oxide), other suitable materials, or combinations of the above materials.

In some embodiments, before forming the second thin film conductive layer 230, an opening exposing the first thin film conductive layer 210 is formed in the first dielectric layer 220 using a photolithography process and an etching process, and the second thin film conductive layer 230 is then deposited in the opening to form the contact portion PH1 of the second thin film conductive layer 230, so that the second thin film conductive layer 230 contacts the first thin film conductive layer 210.

A redistribution structure 300 is located on the thin film circuit structure 200. In the embodiment, the redistribution structure 300 is located on the second dielectric layer 240. In some embodiments, the overall thickness of the redistribution structure 300 is 14 μm to 150 μm.

The redistribution structure 300 includes a first redistribution layer 310, an insulating layer 320, and a second redistribution layer 330 that are sequentially deposited. In some embodiments, at least one contact portion PH2 of the first redistribution layer 310 passes through the second dielectric layer 240 and is electrically connected to the second thin film conductive layer 230. In some embodiments, the first redistribution layer 310 and/or the second redistribution layer 330 are electrically connected to the ground electrode 132 and the bonding structure 134 through a conductive via LH1. The conductive via LH1 passes through the thin film circuit structure 200 and the buffer layer 140, and optionally passes through the insulating layer 320. In some embodiments, the second redistribution layer 330 is electrically connected to the first redistribution layer 310 through at least one conductive via LH2 in the insulating layer 320. The redistribution structure 300 may also include more conductive layers and insulating layers. The disclosure does not limit the number of conductive layers and insulating layers in the redistribution structure 300.

In some embodiments, the materials of the first redistribution layer 310 and the second redistribution layer 330 include copper (Cu), aluminum (Al), gold (Au), silver (Ag), titanium (Ti), nickel (Ni), tungsten (W), conductive oxides (for example, indium tin oxide, indium zinc oxide, etc.), other suitable materials, or combinations of the above materials. In some embodiments, each of the first redistribution layer 310 and the second redistribution layer 330 includes a seed layer and a metal layer formed thereon. The seed layer is, for example, formed by sputtering, chemical plating, or other suitable methods, and the metal layer is formed by electroplating. In some embodiments, the seed layer may be omitted.

In some embodiments, the material of the insulating layer 320 includes an organic material (for example, polyimide, polyethylene terephthalate, epoxy resin, etc.), an inorganic material (for example, silicon nitride, silicon oxide, etc.), or a combination of the above materials. In some embodiments, the method of forming the insulating layer 320 includes pasting a dry film on the first redistribution layer 310 or coating a liquid organic material (for example, a liquid polyimide (PI) material) on the first redistribution layer 310.

In some embodiments, the insulating layer 320 has high transmittance and low dissipation factor (Df). For example, the transmittance of the insulating layer 320 for light rays with wavelengths of 400 nm to 800 nm is greater than or equal to 90%. In some embodiments, the dielectric constant (Dk) of the insulating layer 320 is lower than 4, and the dissipation factor is lower than 0.004.

In some embodiments, the first redistribution layer 310 of the redistribution structure 300 is configured to be used to transmit a ground signal, and the second redistribution layer 330 is configured to be used to transmit a chip power signal and a radio frequency (RF) signal (for example, an RF input signal (RF_in)). In some embodiments, the first thin film conductive layer 210 and the second thin film conductive layer 230 of the thin film circuit structure 200 include a digital signal line and an analog signal line, and the digital signal line and the analog signal line are respectively configured to be used to transmit a digital signal and an analog signal for controlling a circuit in the chip 410A or the thin film circuit structure 200. Since the operating frequencies of the digital signal and the analog signal transmitted in the thin film circuit structure 200 are low, even if the film thicknesses of the first thin film conductive layer 210, the first dielectric layer 220, the second thin film conductive layer 230, and the second dielectric layer 240 in the thin film circuit structure 200 are thin, there will not be significant signal loss. In comparison, since the redistribution structure 300 is used to transmit an RF signal with a high frequency, the insulating layer 320 in the redistribution structure 300 needs to have a thicker thickness. Therefore, the thickness of the insulating layer 320 is greater than the thickness of each of the first dielectric layer 220 and the second dielectric layer 240. In some embodiments, the thickness of the insulating layer 320 is 10 μm to 60 μm. In some embodiments, the thickness of each of the first dielectric layer 220 and the second dielectric layer 240 is 0.03 μm to 1 μm, such as 0.5 μm to 1 μm or 0.7 μm to 1 μm. In some embodiments, the thickness of each of the first thin film conductive layer 210 and the second thin film conductive layer 230 is less than the thickness of each of the first redistribution layer 310 and the second redistribution layer 330. In some embodiments, the thickness of each of the first thin film conductive layer 210 and the second thin film conductive layer 230 is 0.01 μm to 0.7 μm, such as 0.01 μm to 0.3 μm or 0.01 μm to 0.05 μm. In some embodiments, the thickness of each of the first redistribution layer 310 and the second redistribution layer 330 is 2 μm to 10 μm.

In some embodiments, before forming the first redistribution layer 310, an opening exposing the second thin film conductive layer 230 is formed in the second dielectric layer 240 using a photolithography process and an etching process, and the first redistribution layer 310 is then deposited in the opening to form the contact portion PH2 of the first redistribution layer 310, so that the first redistribution layer 310 contacts the second thin film conductive layer 230.

In some embodiments, before forming the first redistribution layer 310 and/or before forming the second redistribution layer 330, a laser drilling process is performed. For example, the laser drilling process is performed to form a laser hole, and the first redistribution layer 310 or the second redistribution layer 330 is then filled in the laser hole to form the conductive via LH1 or the conductive via LH2. In the embodiment, the conductive via LH2 passes through the insulating layer 320, and the second redistribution layer 330 contacts the first redistribution layer 310 through the conductive via LH2. The conductive via LH1 passes through the insulating layer 320, the second dielectric layer 240, the first dielectric layer 220, and the buffer layer 140, and the second redistribution layer 330 contacts the ground electrode 132 and the bonding structure 134 through the conductive via LH1. In the embodiment, since the forming manner of the contact portions PH1 and PH2, the forming manner of the conductive vias LH1 and LH2, and the forming manner of a sidewall of the substrate conductive via 120 are different, the three have different side wall inclination angles.

The chip 410A and the up/down converter 430 are bonded to the second redistribution layer 330. Each antenna electrode 110 overlaps a corresponding one of the chips 410A. In some embodiments, the width of the antenna electrode 110 is greater than or equal to the width of the chip 410A.

In some embodiments, the chip 410A and the up/down converter 430 are respectively bonded to the second redistribution layer 330 through conductive connecting structures 412 and 432. The conductive connecting structures 412 and 432 are, for example, solder, conductive glue, or other suitable structures. In some embodiments, electroless nickel immersion gold (ENIG), immersion silver plating, or other processing may be performed on the surface of the second redistribution layer 330 to improve the yield of a chip bonding process. In some embodiments, before the chip bonding process, an organic material such as organic solderability preservative (OSP) may be formed on the second redistribution layer 330 and may protect a metal pad from rusting (for example, vulcanization or oxidation) due to contact with air to improve the yield of the chip bonding process.

An underfill material 420 is formed between the chip 410A and the second redistribution layer 330 and between the up/down converter 430 and the second redistribution layer 330. In some embodiments, the underfill material 420 may include a thermal interface material (TIM) to facilitate heat dissipation from the chip 410A and the up/down converter 430. For example, the thermal conductivity of the underfill material 420 is greater than 0.3 W/m K.

In the embodiment, compared with a single chip corresponding to multiple antenna units, one chip 410A corresponding to one antenna unit 10A may disperse the heat source, so as to reduce the temperature of the antenna device 1A. Therefore, there is no need to install an additional heat dissipation structure on the chip 410A. In some embodiments, when the output power of the chip 410A is 60 mW and 70 mW, the surface temperatures of the chip 410A are respectively lower than 82 degrees Celsius and lower than 85.5 degrees Celsius.

Through omitting the heat dissipation structure, the weight and the thickness of the antenna device 1A may be significantly reduced while maintaining light transmittance, so that the antenna device 1A may be more easily combined with the vehicle sunroof.

In some embodiments, the chip 410A includes a beamformer integrated circuit (BFIC) or other active/passive elements. In some embodiments, the beamformer integrated circuit includes a variable gain amplifier (VGA), a phase shifter (PS), a signal control and memory circuit, a power amplifier (PA), and/or a low noise amplifier (LNA), etc. In some embodiments, a circuit including an active element may be disposed in the thin film circuit structure 200, so as to reduce circuits required to be disposed in the chip 410A, and therefore, the size of the chip 410A can be reduced. For example, the signal control and memory circuit in the beamformer integrated circuit may be disposed in the thin film circuit structure 200. In some embodiments, through each antenna unit 10A including one BFIC, the signal path between the BFIC and the antenna electrode 110 may be shortened. If one BFIC provides signals to multiple antenna electrodes 110, a longer signal path will need to be configured, thereby reducing the area of a light transmission region of the antenna device. In other words, in the embodiment, through each antenna unit 10A including one chip 410A, the area of the light transmission region LT of the antenna device 1A may be increased.

The printed circuit board 510 is electrically connected to the redistribution structure 300 through the flexible circuit board 620. For example, the flexible circuit board 620 is bonded to a pad P of the second redistribution layer 330 through solder, conductive glue, or other suitable structures. The up/down converter 430 is electrically connected to the printed circuit board 510 and the chip 410A. The up/down converter 430 may be used to convert a signal with a relatively low frequency from the printed circuit board 510 into an RF signal with a high frequency, and the RF signal with the high frequency is further transmitted to the chip 410A for processing.

In some embodiments, the thin film circuit structure 200 and the redistribution structure 300 are configured to be used to transmit various signals, such as ground signals (for example, AGND, DGND, RF_GND, etc.), power signals (for example, AVDD, DVDD, etc.), RF signals, RF enable signals (RF_en), reference voltage signals (Vref), bias voltage regulation signals (Rbias), circuit control signals (for example, CS, CLK, SDI, SDO, PDI, etc.), and antenna signals (for example, horizontally polarized electric field antenna signals (RF_out_H), vertically polarized electric field antenna signals (RF_out_V), etc.). In some embodiments, at least part of the power signals and the circuit control signals are provided by the printed circuit board 510.

In some embodiments, the usage descriptions and the main transmission layers of various signals are shown in Table 1.

TABLE 1

| Signal | Usage description | Main transmission layer |
|---|---|---|
| Power signal | System analog power signal provided to | Second redistribution |
| AVDD | UDC and BFIC (for example, PS, PA, | layer |
| | and/or LNA in BFIC) by power module | |
| Ground signal | Provide system analog ground signal to | First redistribution layer |
| AGND | UDC and BFIC | |
| Power signal | System digital power signal provided to | First and/or second thin |
| DVDD | UDC and BFIC by power module | film conductive layer |
| Ground signal | Connect to ground signal DGND and | First and/or second thin |
| DGND | provide system digital ground signal to | film conductive layer |
| | thin film circuit structure; or connect to | |
| | ground signal AGND to provide system | |
| | analog ground signal to thin film circuit | |
| | structure | |
| Radio frequency | Transmitted between UDC and BFIC, and | Second redistribution |
| signal RF signal | may be sending signal or receiving signal | layer |
| Ground signal | Provide RF analog ground signal to UDC | First redistribution layer |
| RF GND | and BFIC | and/or second |
| | | redistribution layer |
| Reference voltage | Reference voltage provided to BFIC (for | First and/or second thin |
| signal Vref | example, PS in BFIC) by power module | film conductive layer |
| Bias voltage | Regulate bias voltage of PA and/or LNA | Second redistribution |
| regulation signal | in BFIC | layer |
| Rbias | | |
| Antenna signal | Transmitted between BFIC and antenna | First and/or second |
| RF_out | electrode | redistribution layer |
| Radio frequency | Control on and off of radio frequency | First and/or second thin |
| enable signal | circuit or module, so that antenna | film conductive layer |
| RF_en | electrode sends or receives signal | |
| Circuit control | Provide chip select signal to BFIC to | First and/or second thin |
| signal CS | enable read/write operation | film conductive layer |
| Circuit control | Provide clock signal to BFIC | First and/or second thin |
| signal CLK | | film conductive layer |
| Circuit control | Serial data input signal of BFIC | First and/or second thin |
| signal SDI | | film conductive layer |
| Circuit control | Serial data output signal of BFIC | First and/or second thin |
| signal SDO | | film conductive layer |
| Circuit control | Parallel data input signal of BFIC | First and/or second thin |
| signal PDI | | film conductive layer |

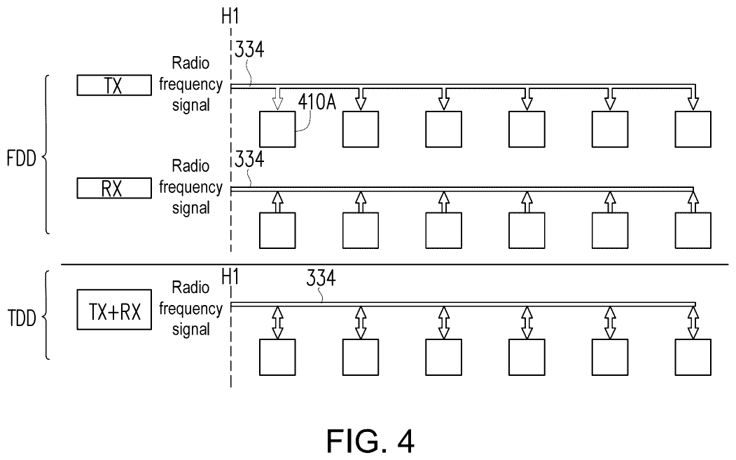

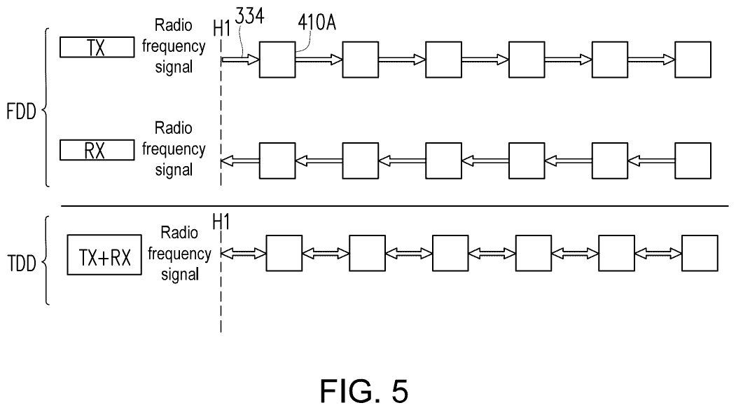

In some embodiments, at least one of the first redistribution layer 310 and the second redistribution layer 330 includes one or more radio frequency signal lines 334, and the radio frequency signal line 334 is configured to transmit the radio frequency signal to the chip 410A. For example, each radio frequency signal line 334 is configured to transmit the radio frequency signals to the chips 410A arranged in a row through a serial feed manner (as shown in FIG. 4). Alternatively, the radio frequency signal line 334 is configured to transmit the radio frequency signals to the chips 410A arranged in a row through a daisy chain manner (as shown in FIG. 5).

In some embodiments, at least one of the first thin film conductive layer 210 and the second thin film conductive layer 230 includes one or more signal lines 211 and 221 for transmitting low frequency signals. The low frequency signals may be analog signals or digital signals and include power signals (for example, DVDD, etc.), radio frequency enable signals (RF_en), reference voltage signals (Vref), bias regulation signals (Rbias), and circuit control signals (for example, CS, CLK, SDI, SDO, PDI, etc.), etc. In some embodiments, the signal lines 211 and 221 may also be referred to as analog signal lines and/or digital signal lines. The thickness of the radio frequency signal line 334 is greater than the thickness of the signal line 211, 221.

In the disclosure, the low frequency signals refer to signals operating at frequencies below 500 MHz, while high frequency signals refer to signals operating at frequencies above 500 MHz (for example, 10 GHz to 300 GHz or 10 GHz to 500 GHz). The high frequency signals include, for example, RF signals and antenna signals (RF_out).

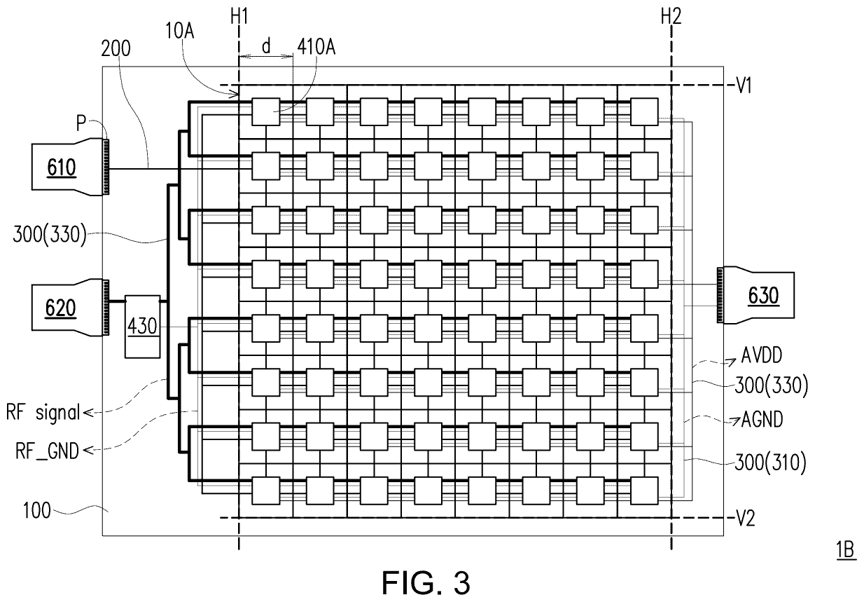

FIG. 3 is a schematic top view of an antenna device 1B according to an embodiment of the disclosure. In the embodiment, the antenna device 1B includes the antenna units 10A arrayed on the transparent substrate 100. FIG. 3 shows the chip 410A in the antenna unit 10A and omits other structures in the antenna unit 10A. It should be noted that in FIG. 3, a line segment may be used to represent a single signal line or multiple signal lines close together.

In some embodiments, a wavelength 2 is the wavelength of a wireless signal that the antenna unit 10A intends to receive or send in the air. A pitch d of the antenna units 10A is approximately one-half of 2. The range of the array of the antenna units 10A may be defined by two parallel lines V1 and V2 and two other parallel lines H1 and H2. The horizontal lines H1 and H2 are perpendicular to the lines V1 and V2.

Please refer to FIG. 3. The flexible circuit boards 610, 620, and 630 are respectively bonded to the corresponding pad P and are used to transmit signals provided by one or more printed circuit boards (not shown) to the thin film circuit structure and/or the redistribution structure located above the transparent substrate 100. In the embodiment, the flexible circuit boards 610 and 620 are located on one side of the transparent substrate 100, and the flexible circuit board 630 is located on the other side of the transparent substrate 100, but the disclosure is not limited thereto. In other embodiments, the flexible circuit boards 610, 620, and 630 are located on the same side of the transparent substrate 100.

In some embodiments, the flexible circuit board 610 is used to transmit a digital signal and/or a power signal provided by the printed circuit board to the chip 410A of the antenna unit 10A. The digital signal and/or the power signal is, for example, transmitted by the thin film circuit structure 200 (for example, the digital signal line and/or the power signal line in the thin film circuit structure 200).

The flexible circuit board 620 is used to transmit an intermediate frequency (IF) or a low frequency signal provided by the printed circuit board to the redistribution structure and the up/down converter 430. The signal is processed by the up/down converter 430 and then converted into an RF signal, and transmitted to the chip 410A of the antenna unit 10A through the redistribution structure. The radio frequency signal is, for example, transmitted by the second redistribution layer 330 of the redistribution structure 300 (for example, the radio frequency signal line in the second redistribution layer 330).

In some embodiments, the flexible circuit boards 610 and 620 are disposed between the lines V1 and V2, and the line H1 defines a side of the array of the antenna units 10A close to the flexible circuit boards 610 and 620. In some embodiments, the radio frequency signal line is designed to have equal impedance from the up/down converter 430 to the line H1 (that is, every point from the up/down converter 430 to the line H1 has equal impedance). In some embodiments, the radio frequency signal line may be distributed from the up/down converter 430 to different antenna units 10A optionally via one or more power dividers (not shown).

The flexible circuit board 630 is used to transmit a power signal (for example, AVDD) and a ground signal (for example, AGND) provided by the printed circuit board to the chip 410A of the antenna unit 10A. For example, the power signal AVDD is transmitted by the second redistribution layer 330 of the redistribution structure 300 (for example, the power signal line in the second redistribution layer 330). The ground signal AGND is transmitted by the first redistribution layer 310 of the redistribution structure 300 (for example, the ground signal line in the second redistribution layer 330).

In some embodiments, in the array of the antenna units 10A (that is, within the range between the line H1 and the line H2), the power signal line, the digital signal line, and the radio frequency signal line extend along the horizontal direction.

FIG. 4 is a radio frequency signal transmission manner of antenna devices according to some embodiments of the disclosure. FIG. 5 is a radio frequency signal transmission manner of other antenna devices according to some embodiments of the disclosure. In the embodiment of FIG. 4, each radio frequency signal line 334 is configured to transmit radio frequency signals to the chips 410A arranged in a row through a serial feed manner. In the embodiment of FIG. 5, each radio frequency signal line 334 is configured to transmit radio frequency signals to the chips 410A arranged in a row through a daisy chain manner.

Please refer to FIG. 4 and FIG. 5. The chip 410A, for example, adopts time division duplex (TDD) technology or frequency division duplex (FDD) technology.

When the chip 410A adopts the FDD technology, transmit beamforming TX and receive beamforming RX are, for example, executed through different antenna unit arrays, wherein the chip 410A in one of the antenna unit arrays executes the transmit beamforming TX of the radio frequency signal, and the chip 410A in another antenna unit array executes the receive beamforming RX.

When the chip 410A adopts the TDD technology, when executing the transmit beamforming TX, the radio frequency signal line 334 provides a radio frequency signal to the chip 410A. When executing the receive beamforming RX, the chip 410A provides a radio frequency signal to the radio frequency signal line 334. In the TDD technology, the chips 410A in the same antenna unit array execute the transmit beamforming TX and the receive beamforming RX at different times.

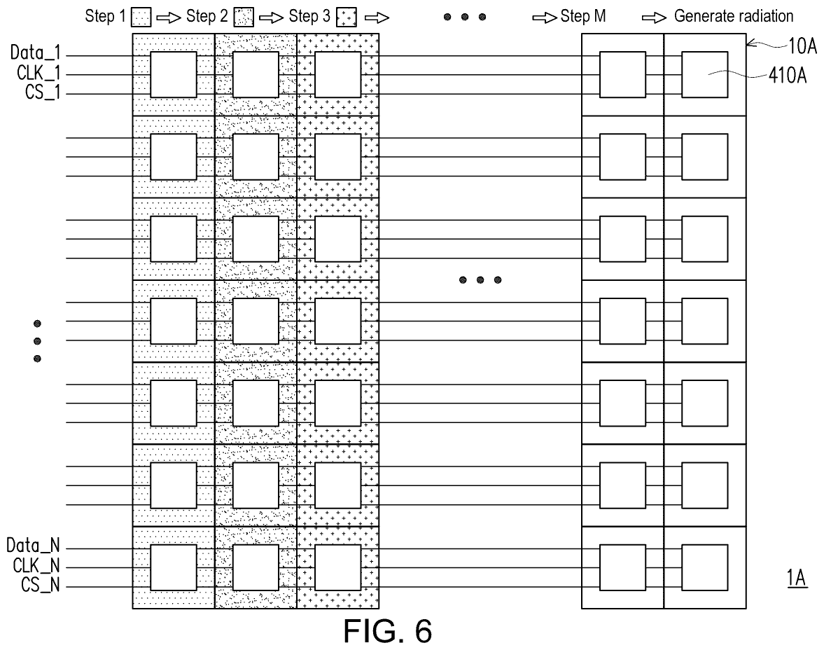

FIG. 6 is a schematic view of data writing/selection of the antenna device 1A according to some embodiments of the disclosure. The antenna units 10A are arranged in an array composed of N rows and M columns.

A signal line Data_1 to a signal line Data_N are respectively electrically connected to the antenna units 10A in the first row to the antenna units 10A in the Nth row (for example, the chip 410A of the antenna unit 10A). A signal line CLK_1 to a signal line CLK_N are respectively electrically connected to the antenna units 10A in the first row to the antenna units 10A in the Nth row (for example, the chip 410A of the antenna unit 10A). A signal line CS_1 to a signal line CS_N are respectively electrically connected to the antenna units 10A in the first row to the antenna units 10A in the Nth row (for example, the chip 410A of the antenna unit 10A).

In some embodiments, the signal line Data_1 to the signal line Data_N are used to transmit at least one of circuit control signals SDI and SDO. The signal line CLK_1 to the signal line CLK_N are used to transmit a circuit control signal CLK. The signal line CS_1 to the signal line CS_N are used to transmit a circuit control signal CS.

In the embodiment, according to step 1, step 2, step 3 . . . to step M, data writing/selection is sequentially performed on the M columns of the antenna units 10A, which may be achieved through the circuit control signal CLK (that is, a clock signal) transmitted by the signal line CLK_1 to the signal line CLK_N. For example, the antenna units 10A in the first column are simultaneously turned on using the signal line CLK_1 to the signal line CLK_N, so that after the signal line Data_1 to the signal line Data_N transmit signals to the antenna units 10A in the first column, the signal line CLK_1 to the signal line CLK_N then transmit signals to the antenna units 10A in the second column, and the antenna units 10A in the second column are turned on, so that signal line Data_1 to the signal line Data_N transmit signals to the antenna units 10A in the second column.

After executing step M, the antenna array is turned on using a clock signal provided by another signal line CLK_M+1 (not shown) and a radio frequency enable signal RF_en provided by a radio frequency enable signal line (not shown), and radiation is generated.

In some embodiments, the circuit control signals are transmitted to all the chips 410A in a serial feed manner. The circuit control signals transmitted to the chips 410A include, for example, SDI, SDO, CLK, CS, etc.

In some embodiments, the circuit control signal PDI, the radio frequency input signal RF_in, the radio frequency enable signal RF_en, the power signal AVDD, the power signal DVDD, the ground signal AGND, and the ground signal RF_GND are input to all the chips 410A using a juxtaposed manner.

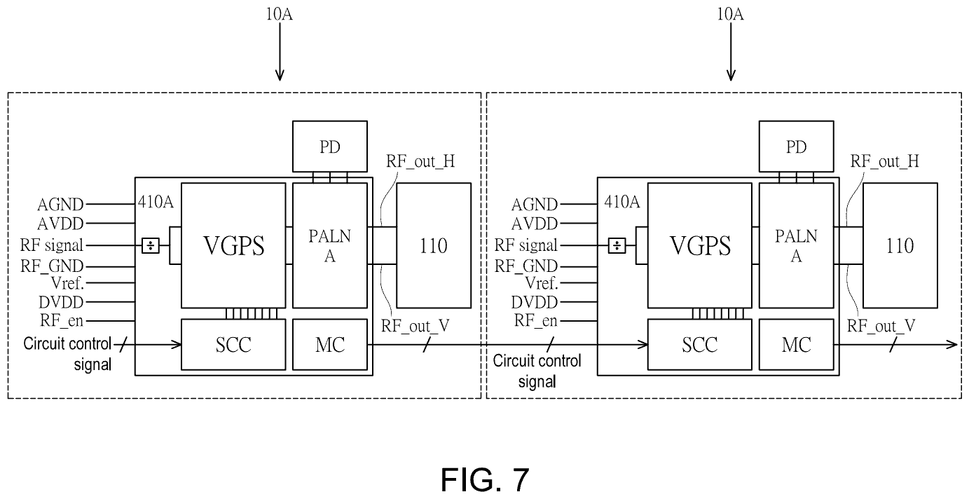

FIG. 7 is a functional block diagram of the antenna device 1A according to an embodiment of the disclosure. In the embodiment, each antenna unit 10A includes one chip 410A, and the chip 410A includes the BFIC.

In the embodiment, the ground signals (for example, AGND, RF_GND, etc.), the power signals (for example, AVDD, DVDD, etc.), the RF signals, the radio frequency enable signals (RF_en), the reference voltage signals (Vref), and various circuit control signals (for example, CS, CLK, SDI, SDO, PDI, etc.) are connected to the chips 410A.

In the embodiment, the circuit control signal is provided to a signal control circuit module SCC and a memory circuit module MC in the chip 410A. The signal control circuit module SCC provides signals to a variable gain amplifier and phase shifter module VGPS.

In the embodiment, a radio frequency signal RF signal is processed by a power divider and then provided to the variable gain amplifier and phase shifter module VGPS. The variable gain amplifier and phase shifter module VGPS provides signals to a power amplifier and/or low noise amplifier module PALNA.

The power amplifier and/or low noise amplifier module PALNA provides a first antenna signal (for example, the horizontally polarized electric field antenna signal (RF_out_H)) and a second antenna signal (for example, the vertically polarized electric field antenna signal (RF_out_V)) to the antenna electrode 110.

In some embodiments, other passive device PD, such as an inductor, a capacitor, and/or a resistor, may be additionally disposed in the antenna unit 10A. The passive device PD is connected to the power amplifier and/or low noise amplifier module PALNA of the chip 410A.

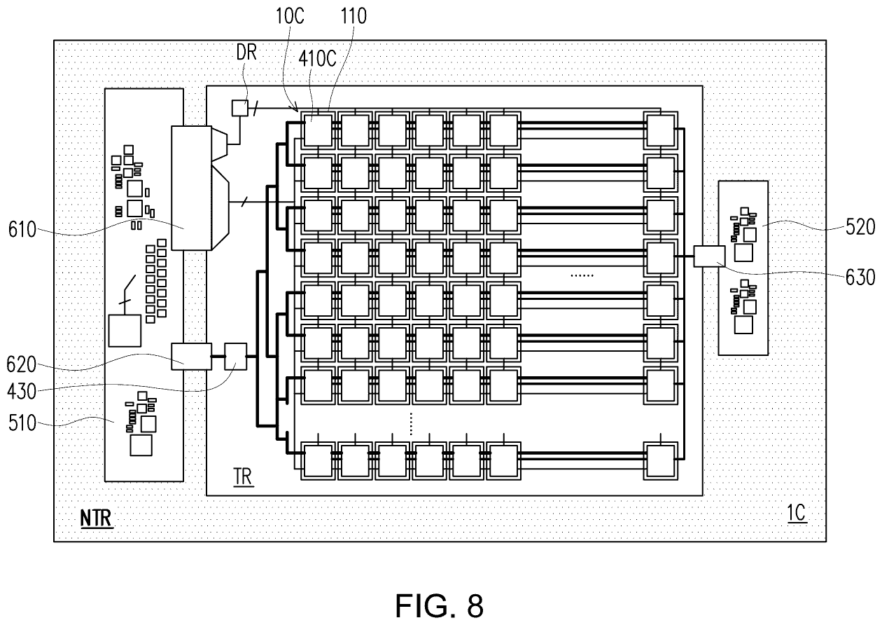

FIG. 8 is a schematic top view of an antenna device 1C according to an embodiment of the disclosure. It must be noted here that the embodiment of FIG. 8 continues to use the reference numerals and some content of the embodiment of FIG. 1, wherein the same or similar numerals are adopted to represent the same or similar elements, and the description of the same technical content is omitted. For the description of the omitted part, reference may be made to the foregoing embodiment and will not be elaborated here.

Please refer to FIG. 8. The antenna device 1C includes a transparent substrate 100 and multiple antenna units 10C disposed on the transparent substrate 100. The antenna units 10C are, for example, arranged in an array. In the embodiment, at least one printed circuit board 510, 520 is electrically connected to the array of the antenna units 10C through at least one flexible circuit board 610, 620, 630. Each antenna unit 10C includes an antenna electrode 110 and a chip 410C electrically connected to the antenna electrode 110. In the embodiment, a gate driving circuit DR connects multiple antenna units 10C in series. For example, the gate driving circuit DR provides a gate signal to a signal control and memory circuit in the antenna unit 10C, and the signal control and memory circuit provides the signal to the chip 410C.

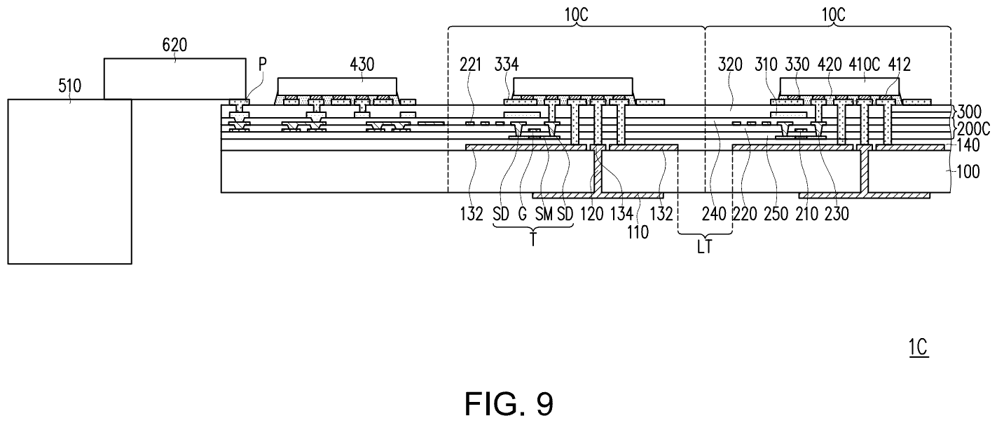

FIG. 9 is a schematic top view of the antenna device 1C according to an embodiment of the disclosure. Please refer to FIG. 9. The antenna device 1C includes the transparent substrate 100 and the antenna units 10C disposed on the transparent substrate 100. The antenna units 10C are, for example, arranged in an array, and there is a light transmission region LT between the antenna units 10C.

A thin film circuit structure 200C includes multiple thin film transistors T. For example, in the embodiment, a gate dielectric layer 250 is further included between the first dielectric layer 220 and the buffer layer 140. Multiple semiconductor layers SM are also included between the gate dielectric layer 250 and the buffer layer 140.

The first thin film conductive layer 210 is located on the gate dielectric layer 250 and includes a gate G overlapping the semiconductor layer SM. The first dielectric layer 220 covers the gate G. The second thin film conductive layer 230 is located on the first dielectric layer 220 and includes multiple sources/drains SD. In the embodiment, each thin film transistor T includes a corresponding semiconductor layer SM, a corresponding gate G, and a corresponding source/drain SD. In the embodiment, the thin film transistor T is a top gate thin film transistor, but the disclosure is not limited thereto. In other embodiments, the thin film transistor T is a bottom gate thin film transistor, a double gate thin film transistor, or other types of thin film transistors.

The thin film transistor T is electrically connected to the chip 410C and the signal line 221 (for example, a digital signal line) in the thin film circuit structure 200C. The thickness of the signal line 221 is less than the thickness of the radio frequency signal line 334. The signal line 221 is, for example, used to transmit any of the digital signals described in the foregoing embodiment.

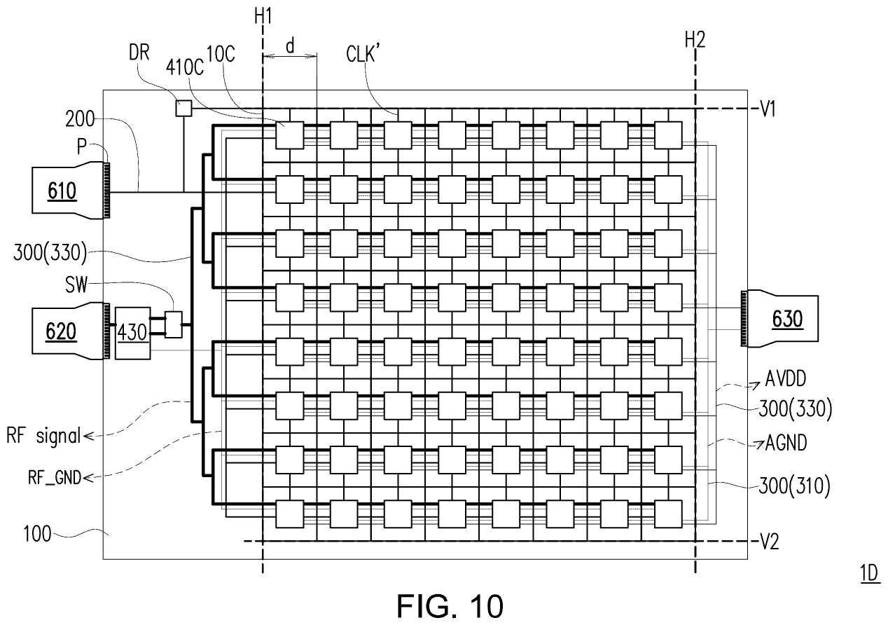

FIG. 10 is a schematic top view of an antenna device 1D according to an embodiment of the disclosure. It must be noted here that the embodiment of FIG. 10 continues to use the reference numerals and some content of the embodiment of FIG. 3, wherein the same or similar numerals are adopted to represent the same or similar elements, and the description of the same technical content is omitted. For the description of the omitted part, reference may be made to the foregoing embodiments and will not be elaborated here.

In the embodiment, the antenna device 1D includes multiple antenna units 10C arrayed on a transparent substrate 100. FIG. 10 shows the chip 410C in the antenna unit 10C and omits other structures in the antenna unit 10C. It should be noted that in FIG. 10, a line segment may be used to represent a single signal line or multiple signal lines close together.

In some embodiments, the flexible circuit board 610 is used to transmit a digital signal and/or a power signal provided by the printed circuit board to the chip 410C of the antenna unit 10C. The digital signal and/or the power signal is, for example, transmitted by the thin film circuit structure 200 (for example, the digital signal line and/or the power signal line in the thin film circuit structure 200). In addition, the flexible circuit board 610 is also electrically connected to the gate driving circuit DR, and a clock signal (or a gate signal) is provided to the antenna unit 10C through the gate driving circuit DR and multiple signal lines CLK′ (also referred to as clock signal lines or gate signal lines).

In some embodiments, the radio frequency signal line is distributed from the up/down converter 430 to the antenna units 10C in different rows optionally via one or more power dividers SW. The radio frequency signal line is designed to have equal impedance from the power divider SW to the line H1 (that is, every point from the power divider SW to the line H1 has equal impedance).

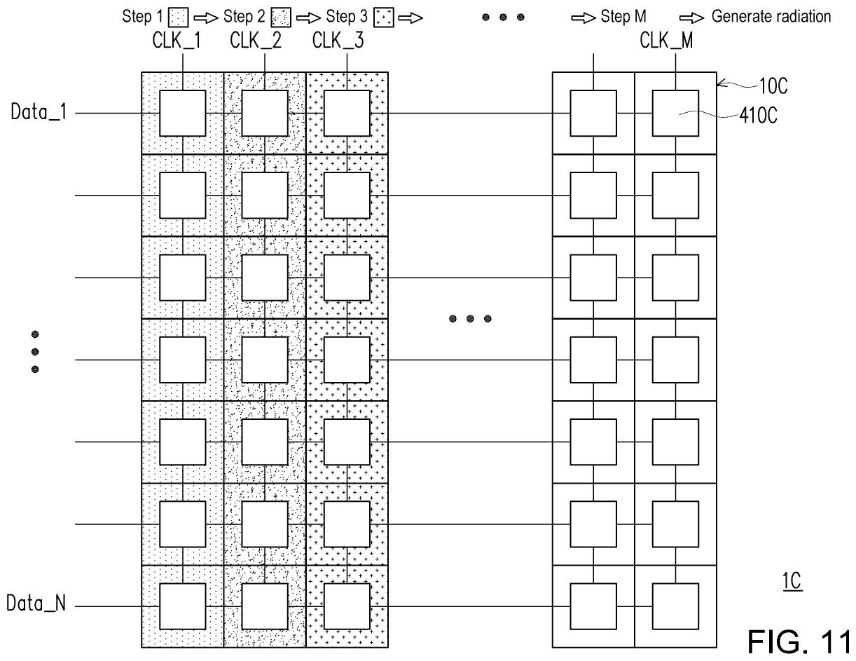

FIG. 11 is a schematic view of data writing/selection of the antenna device 1C according to some embodiments of the disclosure. The antenna units 10C are arranged in an array composed of N rows and M columns.

The signal line Data_1 to the signal line Data_N are respectively electrically connected to the antenna units 10C in the first row to the antenna units 10C in the Nth row (for example, the signal control and memory circuit of the antenna unit 10C).

In some embodiments, the signal line Data_1 to the signal line Data_N are used to transmit at least one of the circuit control signals SDI and SDO.

The signal line CLK_1 to the signal line CLK_M are respectively electrically connected to the antenna unit 10C in the first column to the antenna units 10C in the Mth column (for example, the signal control and memory circuit of the antenna unit 10C).

In the embodiment, according to step 1, step 2, step 3 . . . to step M, data writing/selection is sequentially performed on the M rows of the antenna units 10C, which may be achieved through clock signals (which may be gate signals for controlling transistors in some embodiments) transmitted by the signal line CLK_1 to the signal line CLK_M. The signal line CLK_1 to the signal line CLK_M are electrically connected to the gate driving circuit DR (please refer to FIG. 10).

After executing step M, the antenna array is turned on using a clock signal provided by another signal line CLK_M+1 (not shown) and the radio frequency enable signal RF_en provided by the radio frequency enable signal line (not shown), and radiation is generated.

In some embodiments, the circuit control signals are transmitted to the antenna units 10C in the same row along the horizontal direction. The circuit control signals include, for example, SDI, SDO, CLK, CS, etc.

The clock signals (which may also be referred to as gate signals in some embodiments) are input to the antenna units 10C in the same column along the vertical direction (for example, the signal control and memory circuit of the antenna unit 10C or the chip 410C).

In some embodiments, the circuit control signal PDI, the radio frequency enable signal RF_en, the radio frequency input signal RF_in, the power signal AVDD, the power signal DVDD, the ground signal AGND, and the ground signal RF_GND are input to all the chips 410C using a juxtaposed manner.

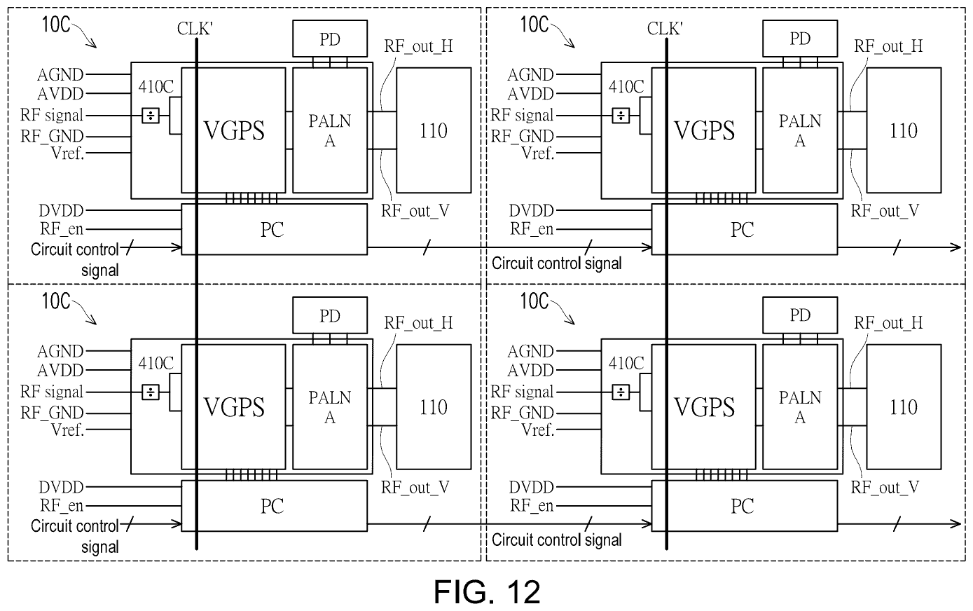

FIG. 12 is a functional block diagram of the antenna device 1C according to an embodiment of the disclosure. In the embodiment, each antenna unit 10C includes one chip 410C and a phase control module PC (which includes, for example, a signal control and memory circuit). The chip 410C includes a BFIC. The phase control module PC is disposed in the thin film circuit structure 200C (please refer to FIG. 9) and includes multiple thin film transistors T (or also referred to as switching elements).

In the embodiment, ground signals (for example, AGND, RF_GND, etc.), power signals (for example, AVDD, etc.), RF signals, and reference voltage signals (Vref) are connected to the chip 410C, and various circuit control signals (for example, SDI, SDO, PDI, etc.), radio frequency enable signals (RF_en), and power signals (for example, DVDD, etc.) are connected to the phase control module PC. The signal lines CLK′ are respectively connected to the phase control modules PC of the antenna units 10C in different columns.

In the embodiment, the circuit control signal is provided to the phase control module PC. The phase control module PC provides the signal to the chip 410C, such as the variable gain amplifier and phase shifter module VGPS in the chip 410C.

In the embodiment, the radio frequency signal RF signal is processed by a divider and then provided to the variable gain amplifier and phase shifter module VGPS. The variable gain amplifier and phase shifter module VGPS provides the signal to the power amplifier and/or low noise amplifier module PALNA.

The power amplifier and/or low noise amplifier module PALNA provides the first antenna signal (for example, the horizontally polarized electric field antenna signal (RF_out_H)) and the second antenna signal (for example, the vertically polarized electric field antenna signal (RF_out_V)) to the antenna electrode 110.

In some embodiments, other passive device PD, such as an inductor, a capacitor, and/or a resistor, may be additionally disposed in the antenna unit 10C. The passive device is the power amplifier and/or low noise amplifier module PALNA connected to the chip 410C.

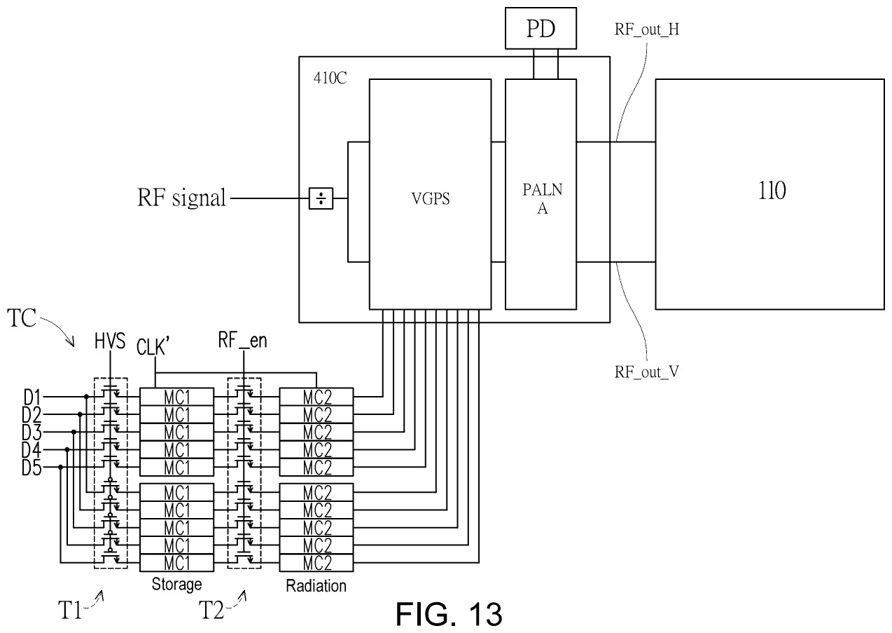

FIG. 13 is a schematic circuit diagram of an antenna unit according to an embodiment of the disclosure. It must be noted here that the embodiment of FIG. 13 continues to use the reference numerals and some content of the embodiment of FIG. 12, wherein the same or similar numerals are adopted to represent the same or similar elements, and the description of the same technical content is omitted. For the description of the omitted part, reference may be made to the foregoing embodiments and will not be elaborated here.

Please refer to FIG. 13. In the embodiment, a signal control and memory circuit TC (that is, the phase control module PC in FIG. 12) includes multiple first switching elements T1, multiple first memory circuits MC1, multiple second switching elements T2, and multiple second memory circuits MC2. The first switching elements T1 are respectively electrically connected to the first memory circuits MC1. Each second switching element T2 is electrically connected to a corresponding one of the first memory circuits MC1 and a corresponding one of the second memory circuits MC2. The second memory circuit MC2 of the signal control and memory circuit TC is electrically connected to the chip 410C.

Signal lines D1 to D5 are connected to the first switching elements T1. In some embodiments, each of the signal lines D1 to D5 is connected to corresponding two of the first switching elements T1. A horizontal polarization/vertical polarization selection line HVS is electrically connected to a gate of the first switching element T1, and provides a gate signal to the gate of the first switching element T1 to control the on and off of the first switching element T1. In some embodiments, among the 10 first switching elements T1 shown in FIG. 13, the top 5 first switching elements T1 correspond to the first memory circuits MC1 related to the horizontally polarized electric field antenna signal (RF_out_H), and the bottom 5 first switching elements T1 correspond to the first memory circuits MC1 related to the vertically polarized electric field antenna signal (RF_out_V). Through the design of the top 5 first switching elements T1 and the bottom 5 first switching elements T1 including transistors of different types, such as the top 5 first switching elements T1 being one of n-type transistors and p-type transistors, and the bottom 5 first switching elements T1 being the other one of n-type transistors and p-type transistors, the top 5 first switching elements T1 and the bottom 5 first switching elements T1 have different on voltages. In some embodiments, the number of the first switching elements T1 may be adjusted according to requirements.

A radio frequency enable signal line is electrically connected to a gate of the second switching element T2 and provides a radio frequency enable signal RF_en to the gate of the second switching element T2 to control the on and off of the second switching element T2.

In some embodiments, the horizontal polarization/vertical polarization selection line HVS, the radio frequency enable signal line, the signal lines D1 to D5, the first switching element T1, the first memory circuit MC1, the second switching element T2, and a second memory circuit M1 are disposed in the thin film circuit structure 200C (please refer to FIG. 9). For example, at least one of the first thin film conductive layer 210 and the second thin film conductive layer 220 includes the horizontal polarization/vertical polarization selection line HVS and the radio frequency enable signal line.

In some embodiments, a circuit control signal CLK (that is, a clock signal) provided by the signal line CLK′ is used to control the storage of the first memory circuit MC1, and the first memory circuit MC1 may be used to preload data to be written next. The radio frequency enable signal RF_en is used to control the second memory circuit MC2, and the second memory circuit is used to maintain a current state of radiation. The signal line CLK′ of FIG. 13, for example, corresponds to the signal line CLK_1 to the signal line CLK_M of FIG. 11. The gate driving circuit is electrically connected to the first memory circuit MC1 and the second memory circuit MC2 through the signal line CLK′.

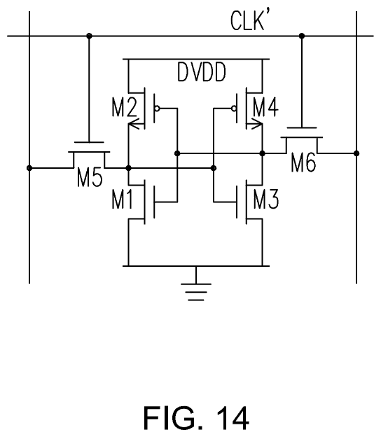

In some embodiments, the circuit layout of each of the first memory circuits MC1 and the second memory circuits MC2 is as shown in FIG. 14. Each memory circuit includes thin film transistors M1, M2, M3, M4, M5, and M6. The thin film transistors M1, M2, M3, M4, M5, and M6 are disposed in the thin film circuit structure 200C (please refer to FIG. 9). In some embodiments, a power signal DVDD is provided to the thin film transistors M2 and M4 of the memory circuit, and the circuit control signal CLK (that is, the clock signal) is provided to the thin film transistors M5 and M6 of the memory circuit. In some embodiments, the thin film transistors M1 and M3 are connected to a ground signal.

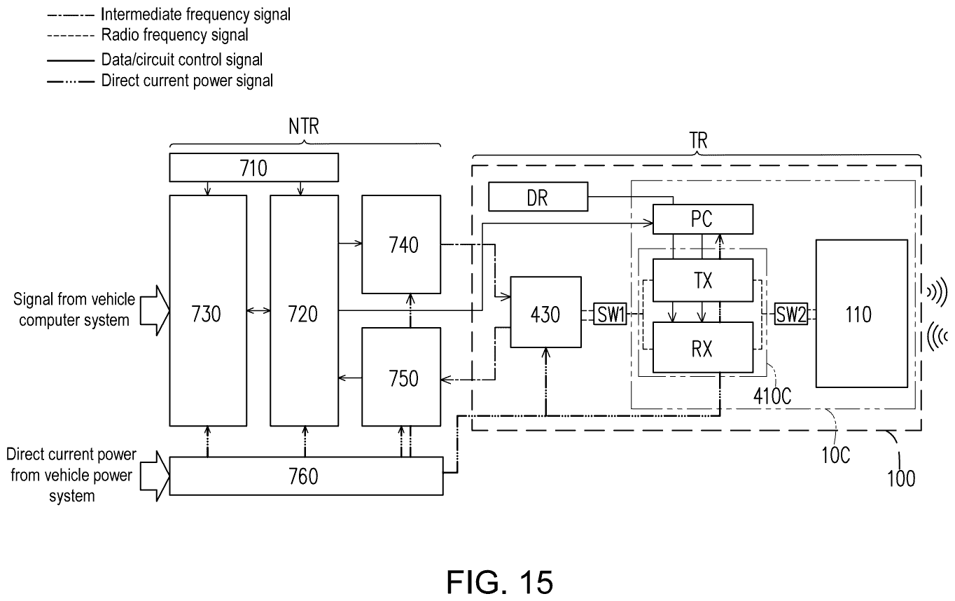

FIG. 15 is a functional block diagram of an antenna device according to an embodiment of the disclosure. The non-transparent region NTR of the antenna device includes a global positioning system/gravity meter module 710, a field programmable logic gate array module 720, a modulator/demodulator module 730, a digital to analog converter 740, and an analog to digital converter 750, and a power module 760. The global positioning system/gravity meter module 710, the field programmable logic gate array module 720, the modulator/demodulator module 730, the digital to analog converter 740, the analog to digital converter 750, and the power module 760 are, for example, disposed on the printed circuit board (the printed circuit board 510, 520 as shown in FIG. 1).

In the embodiment, since the antenna device is installed on a vehicle, a vehicle computer system may provide a signal to the modulator/demodulator module 730, and the vehicle power system may provide a direct current power to the power module 760.

Data/circuit control signals are transmitted between the global positioning system/gravity meter module 710 and the field programmable logic gate array module 720, between the global positioning system/gravity meter module 710 and the modulator/demodulator module 730, between the field programmable logic gate array module 720 and the digital to analog converter 740, and between the field programmable logic gate array module 720 and the analog to digital converter 750.

In some embodiments, the field programmable logic gate array module 720 may perform digital signal processing and timing management. The field programmable logic gate array module 720 may transmit data to the digital to analog converter 740 in the form of digital signals or receive data from the analog to digital converter 750 in the form of digital signals.

The power module 760 provides direct current signals to the field programmable logic gate array module 720, the modulator/demodulator module 730, the digital to analog converter 740, and the analog to digital converter 750. In addition, the power module 760 also provides direct current signals to the up/down converter 430 and the antenna unit 10C disposed in the transparent region TR. The direct current signals include, for example, ground signals (for example, AGND, DGND, RF_GND, etc.), power signals (for example, AVDD, DVDD, etc.), reference voltage signals (Vref), or other similar signals.

The transparent region TR of the antenna device includes the gate driving circuit DR, the up/down converter 430, a power divider SW1, and the antenna unit 10C. In the embodiment, the antenna unit 10C includes the chip 410C, the phase control module PC (for example, the signal control and memory circuit TC shown in FIG. 13), a power divider SW2, and the antenna electrode 110.

The up/down converter 430 receives an intermediate frequency signal from the digital to analog converter 740 or transmits an intermediate frequency signal to the analog to digital converter 750. In some embodiments, the frequency of the intermediate frequency signal is less than 10 GHz. The up/down converter 430 may convert an intermediate frequency signal into a radio frequency signal with a high frequency or convert a radio frequency signal with a high frequency into an intermediate frequency signal. In some embodiments, the frequency of the radio frequency signal is greater than or equal to 10 GHz.

The radio frequency signal is transmitted to the chip 410C via the power divider SW1 and is processed in the chip 410C. It must be noted here that the chip 410C in FIG. 15 adopts the TDD technology to perform the transmit beamforming TX and the receive beamforming RX. The gate driving circuit DR provides a circuit control signal (for example, a gate signal or a clock signal) to the phase control module PC, and the field programmable logic gate array module 720 provides a circuit control signal (for example, a clock signal) to the phase control module PC. The phase control module PC outputs the circuit control signal to the chip 410C, and performs the transmit beamforming TX and the receive beamforming RX. In some embodiments, the gate driving circuit DR and the phase control module PC may be disposed in the thin film circuit structure 200C (please refer to FIG. 9). In some embodiments, the phase control module PC may be integrated into the chip 410C. In some embodiments, the gate driving circuit DR may be disposed in other chips and bonded to the redistribution structure 300 (please refer to FIG. 9).

The power divider SW2 distributes the radio frequency signal between the chip 410C and the antenna electrode 110. In some embodiments, the power divider SW2 may be integrated into the chip 410C or disposed in the thin film circuit structure 200C (please refer to FIG. 9).

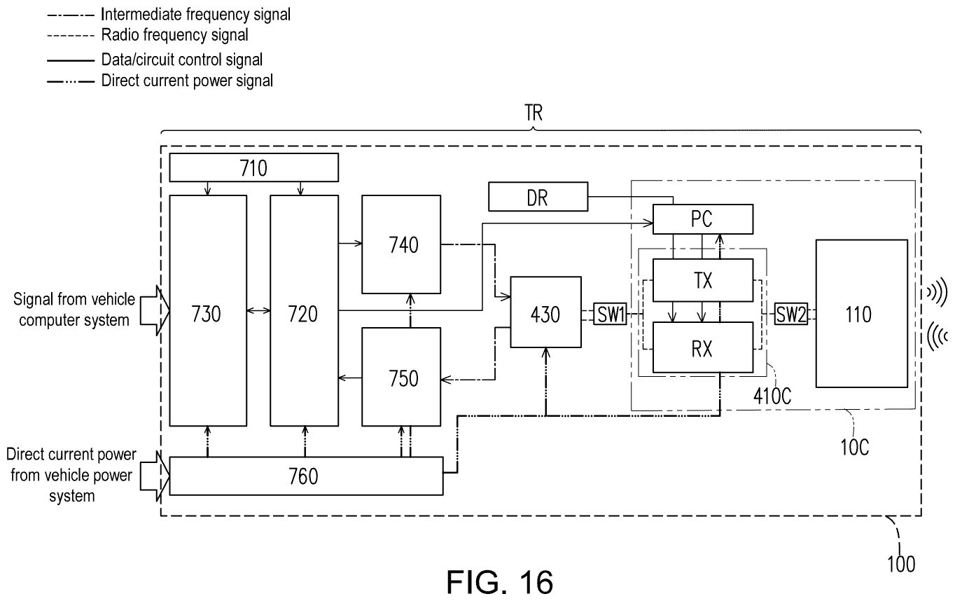

In the embodiment, the global positioning system/gravity meter module 710, the field programmable logic gate array module 720, the modulator/demodulator module 730, the digital to analog converter 740, the analog to digital converter 750, and the power module 760 are disposed in the non-transparent region NTR, but the disclosure is not limited thereto. In other embodiments, one or more of the global positioning system/gravity meter module 710, the field programmable logic gate array module 720, the modulator/demodulator module 730, the digital to analog converter 740, the analog to digital converter 750, and the power module 760 are disposed in the transparent region TR, that is, disposed above the transparent substrate 100, as shown in FIG. 16.

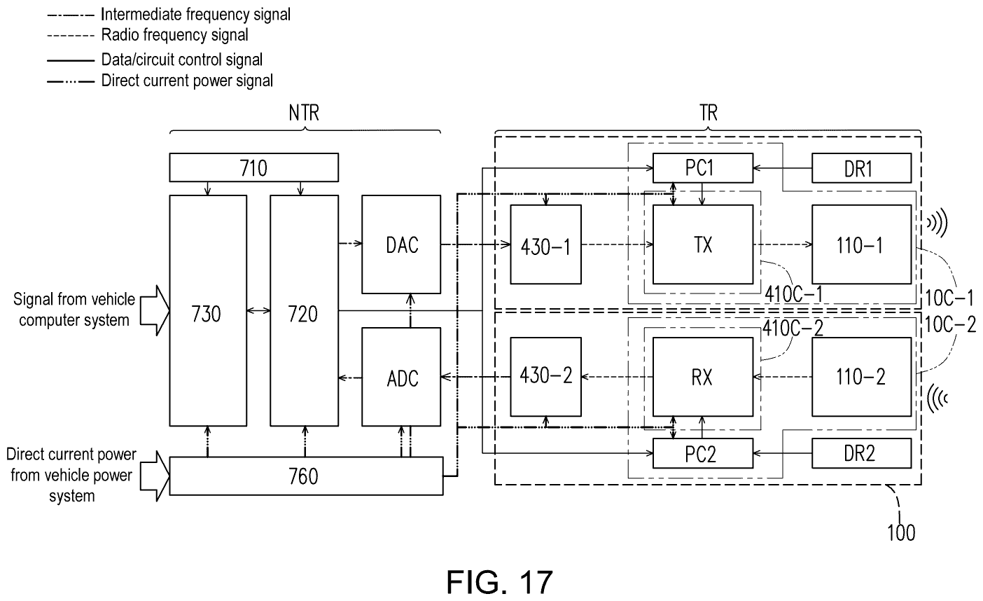

FIG. 17 is a functional block diagram of yet another antenna device according to an embodiment of the disclosure. It must be noted here that the embodiment of FIG. 17 continues to use the reference numerals and some content of the embodiment of FIG. 15, wherein the same or similar numerals are adopted to represent the same or similar elements, and the description of the same technical content is omitted. For the description of the omitted part, reference may be made to the foregoing embodiments and will not be elaborated here.

The difference between an antenna device of FIG. 17 and the antenna device of FIG. 15 is that a chip in the antenna device of FIG. 17 adopts FDD technology and respectively uses different antenna unit arrays to perform transmit beamforming TX and receive beamforming RX.

In an array composed of antenna units 10C-1, an up/down converter 430-1 provides a radio frequency signal to a chip 410C-1 and performs the transmit beamforming TX. An antenna 110-1 outputs a corresponding radiation signal. In some embodiments, a gate driving circuit DR1 provides a circuit control signal (for example, a gate signal or a clock signal) to a phase control module PC1, and the field programmable logic gate array module 720 provides a circuit control signal (for example, a clock signal) to the phase control module PC1. The phase control module PC1 outputs a circuit control signal to the chip 410C-1 and performs the transmit beamforming TX.

In the array composed of the antenna units 10C-2, an antenna 110-2 receives the corresponding radiation signal. A chip 410C-2 performs the receive beamforming RX. An up/down converter 430-2 receives a radio frequency signal from the chip 410C-2. In some embodiments, a gate driving circuit DR2 provides a circuit control signal (for example, a gate signal or a clock signal) to a phase control module PC2, and the field programmable logic gate array module 720 provides a circuit control signal (for example, a clock signal) to the phase control module PC2. The phase control module PC2 outputs a circuit control signal to the chip 410C-2 and performs the receive beamforming RX.

In some embodiments, the array composed of the antenna units 10C-1 and the array composed of the antenna units 10C-2 may be disposed in different areas on the same transparent substrate 100 or may be respectively disposed on two transparent substrates 100.

In summary, the antenna device of the disclosure includes the thin film circuit structure, and the thin film conductive layer in the thin film circuit structure may be used to transmit the circuit control signal. Since the thickness of the thin film conductive layer is thin, the overall thickness of the antenna device can be reduced. In addition, since each antenna unit includes the chip, the heat source of the antenna device can be dispersed.

What is claimed is:

1. An antenna device, comprising:
a transparent substrate;
a thin film circuit structure, located above a first surface of the transparent substrate and comprising a first thin film conductive layer;
a redistribution structure, located on the thin film circuit structure and comprising a first redistribution layer, wherein a thickness of the first thin film conductive layer is less than a thickness of the first redistribution layer;
a plurality of chips, bonded to the redistribution structure; and
a plurality of antenna electrodes, located above a second surface of the transparent substrate opposite to the first surface, wherein each of the antenna electrodes overlaps a corresponding one of the chips.

2. The antenna device according to claim 1, wherein the thin film circuit structure comprises a signal control and memory circuit, wherein the signal control and memory circuit is electrically connected to one of the chips.

3. The antenna device according to claim 2, wherein the signal control and memory circuit comprises a plurality of first switching elements and a plurality of first memory circuits, and the first switching elements are respectively electrically connected to the first memory circuits.

4. The antenna device according to claim 3, wherein a gate driving circuit is electrically connected to gates of the first memory circuits.

5. The antenna device according to claim 3, wherein the signal control and memory circuit further comprises a plurality of second switching elements and a plurality of second memory circuits, and each of the second switching elements is electrically connected to a corresponding one of the first memory circuits and a corresponding one of the second memory circuits.

6. The antenna device according to claim 5, wherein the thin film circuit structure further comprises a second thin film conductive layer, wherein one of the first thin film conductive layer and the second thin film conductive layer comprises a radio frequency enable signal line, and the radio frequency enable signal line is electrically connected to gates of the second switching elements.

7. The antenna device according to claim 1, further comprising:
at least one printed circuit board and at least one flexible circuit board, wherein the at least one printed circuit board is electrically connected to the redistribution structure through the at least one flexible circuit board, the at least one printed circuit board is disposed in a non-transparent region of the antenna device, and the antenna electrodes and the chips are disposed in a transparent region of the antenna device.

8. The antenna device according to claim 7, wherein the at least one printed circuit board comprises a field programmable logic gate array module.

9. The antenna device according to claim 7, further comprising:
an up/down converter, electrically connected to the at least one printed circuit board and the chips, and the up/down converter being disposed in the transparent region.

10. The antenna device according to claim 1, wherein the redistribution structure further comprises a second redistribution layer, wherein at least one of the first redistribution layer and the second redistribution layer comprises one or more radio frequency signal lines, wherein the one or more radio frequency signal lines are configured to transmit radio frequency signals to a plurality of the chips through a daisy chain manner.

11. The antenna device according to claim 1, wherein the redistribution structure further comprises a second redistribution layer, wherein at least one of the first redistribution layer and the second redistribution layer comprises one or more radio frequency signal lines, wherein the one or more radio frequency signal lines are configured to transmit radio frequency signals to a plurality of the chips through a serial feed manner.

12. The antenna device according to claim 1, further comprising a field programmable logic gate array module disposed on the transparent substrate.

13. The antenna device according to claim 1, wherein the thin film circuit structure comprises a second thin film conductive layer, wherein at least one of the first thin film conductive layer and the second thin film conductive layer comprises one or more digital signal lines, and the redistribution structure further comprises a second redistribution layer, wherein at least one of the first redistribution layer and the second redistribution layer comprises one or more radio frequency signal lines, wherein a thickness of the one or more radio frequency signal lines is greater than a thickness of the one or more digital signal lines, wherein the one or more radio frequency signal lines are configured to transmit radio frequency signals to a plurality of the chips.

14. The antenna device according to claim 13, wherein the one or more digital signal lines are configured to be used to transmit digital signals to the plurality of the chips.
